(19) United States
(12) Patent Application Publication
(10) Pub. No.: US 2015/0028299 A1
(43) Pub. Date: Jan. 29, 2015

(54) ORGANIC LIGHT EMITTING DIODE DISPLAY AND METHOD FOR MANUFACTURING THE SAME

(71) Applicant: SAMSUNG DISPLAY CO., LTD., Yongin-si (KR)

(72) Inventors: Myung Jong Jung, Yongin-si (KR); Jin Woo Park, Yangju-si (KR)

(73) Assignee: SAMSUNG DISPLAY CO., LTD., Yongin-si (KR)

(21) Appl. No.: 14/191,325

(22) Filed: Feb. 26, 2014

(30) Foreign Application Priority Data
Jul. 24, 2013 (KR) 10-2013-0087489

(51) Int. Cl. H01L 27/32; H01L 51/56

(52) U.S. Cl. CPC H01L 27/3244; H01L 51/56
USPC 257/40; 438/34

(57) ABSTRACT

An organic light emitting diode display including: a pixel electrode; a hole auxiliary layer on the pixel electrode; a passivation layer on the hole auxiliary layer; an organic light emitting layer on the passivation layer; an electron auxiliary layer on the organic light emitting layer; and a common electrode on the electron auxiliary layer is disclosed. A method for manufacturing an organic light emitting diode display is also disclosed.

### CROSS-REFERENCE TO RELATED APPLICATION

This application claims priority to and the benefit of Korean Patent Application No. 10-2013-0087489, filed in the Korean Intellectual Property Office on Jul. 24, 2013, the entire content of which is incorporated herein by reference.

### BACKGROUND

1. Field

Aspects of embodiments of the present invention relate to an organic light emitting diode display and a method for manufacturing the same.

2. Description of the Related Art

An organic light emitting diode display includes two electrodes and an organic light emitting member positioned between the two electrodes. Electrons injected from a cathode serving as one electrode and holes injected from an anode serving as the other electrode are coupled in the organic light emitting member so as to form excitons. The excitons release energy and light is emitted.

Among methods for forming an organic light emitting layer of organic light emitting members, a method for forming an organic light emitting layer using a laser induced thermal imaging process is capable of not being influenced by the solubility characteristic of a transfer layer that forms the organic light emitting layer. The laser induced thermal imaging process is performed as follows: light emitted from a laser is converted into thermal energy, and a transfer layer is transferred onto a substrate of an organic light emitting diode display as a result of the converted thermal energy, thereby forming an organic light emitting layer.

During the laser induced thermal imaging process, a light-to-heat conversion layer converts light from the laser into heat to expand the transfer layer under the light-to-heat conversion layer. Then, the transfer layer is separated from a donor film and transferred onto the substrate of the organic light emitting diode display. In this case, since the material patterned through the energy obtained by converting light from the laser into heat is transferred onto the substrate, the transfer layer may be damaged as a result of heat and infrared light applied to the light-to-heat conversion layer being transmitted to the transfer layer.

Thus, the organic light emitting layer may be damaged, which can degrade the display quality of the organic light emitting diode display.

The above information disclosed in this Background section is only for enhancement of understanding of the background of the invention and therefore it may contain information that does not form the prior art that is already known in this country to a person of ordinary skill in the art.

### SUMMARY

Aspects of embodiments of the present invention have been provided in an effort to provide an organic light emitting diode display which includes a passivation layer on and/or between organic layers to prevent an organic light emitting layer from being damaged by thermal energy (or to reduce damage to the organic light emitting layer caused by thermal energy) and prevent (or reduce) reduction in display quality of the organic light emitting diode display, when a transfer layer is transferred onto a substrate of the organic light emitting diode display by a laser induced thermal imaging process, and a method for manufacturing the same.

According to an exemplary embodiment of the present invention, an organic light emitting diode display includes: a pixel electrode; a hole auxiliary layer on the pixel electrode; a passivation layer on the hole auxiliary layer; an organic light emitting layer on the hole auxiliary layer; an electron auxiliary layer on the organic light emitting layer; and a common electrode on the electron auxiliary layer.

The passivation layer may be for reducing formation of a mixed layer of the organic light emitting layer and the hole auxiliary layer caused by heat.

The hole auxiliary layer may include a hole injection layer on the pixel electrode and a hole transport layer on the hole injection layer, and the electron auxiliary layer may include an electron transport layer on the organic light emitting layer and an electron injection layer on the electron transport layer.

The passivation layer may include a material having a higher melting temperature than the organic light emitting layer and the hole transport layer.

The passivation layer may include a material that resists a phase change at a temperature of 400 to 600° C.

The passivation layer may be for preventing mixture of the organic light emitting layer and the hole transport layer.

The passivation layer may include a material selected from the group consisting of magnesium (Mg), silver (Ag), aluminum (Al), chromium (Cr) and gold (Au).

The passivation layer may be for insulating the hole auxiliary layer from heat generated during the manufacture of the organic light emitting diode display.

In some embodiments, the organic light emitting diode display does not include a mixed layer including a mixture of a material of the organic light emitting layer and a material of the hole auxiliary layer.

The passivation layer may be for preventing a mixed layer of the organic light emitting layer and the hole auxiliary layer from being generated by heat.

Another exemplary embodiment of the present invention provides a method for manufacturing an organic light emitting diode display, the method including: providing a thin film transistor, a pixel electrode and a hole auxiliary layer on a substrate; providing a light-to-heat conversion layer on a base film, an organic light emitting layer on the light-to-heat conversion layer, and a passivation layer on the organic light emitting layer, thereby manufacturing a donor film; transferring the organic light emitting layer and the passivation layer of the donor film onto the hole auxiliary layer of the substrate using a laser; providing the passivation layer on the hole auxiliary layer and the organic light emitting layer on the passivation layer by removing the donor film after transferring the organic light emitting layer and the passivation layer onto the hole auxiliary layer of the substrate; and providing an electron auxiliary layer on the organic light emitting layer.

The hole auxiliary layer may include: a hole injection layer on the pixel electrode and a hole transport layer on the hole injection layer; and the electron auxiliary layer may include an electron transport layer on the organic light emitting layer and an electron injection layer on the electron transport layer.

The passivation layer and the organic light emitting layer may be transferred onto the hole transport layer on the substrate.

The passivation layer may include a material having a higher melting temperature than the organic light emitting layer and the hole transport layer.

The passivation layer may include a material that resists a phase change at a temperature of 400 to 600° C.

The passivation layer may prevent mixing of the organic light emitting layer and the hole transport layer caused by heat generated from the light-to-heat conversion layer of the donor film.

The passivation layer may include one material selected from the group consisting of magnesium (Mg), silver (Ag), aluminum (Al), chromium (Cr) and gold (Au).

The passivation layer may reduce mixing of the organic light emitting layer and the hole transport layer caused by heat generated from the light-to-heat conversion layer of the donor film.

The passivation layer may insulate the hole auxiliary layer from heat generated by the light-to-heat conversion layer.

In some embodiments, the organic light emitting diode display does not include a mixed layer including a mixture of a material of the organic light emitting layer and a material of the hole auxiliary layer.

According to embodiments of the present invention, the passivation layer is formed in (or included in) the organic layer of the organic light emitting diode display, thereby preventing (or reducing) reduction in the display quality of the organic light emitting diode display which may occur when the organic layer is damaged by thermal energy generated from the light-to-heat conversion layer. The passivation layer may be between (e.g., directly contacting both or formed between) the organic light emitting layer and the hole auxiliary layer, thereby minimizing (or reducing) thermal damage of the organic light emitting layer and the hole auxiliary layer, which may occur due to heat generated from the light-to-heat conversion layer of the donor film, and preventing (or reducing) the generation of a mixed layer during a laser induced thermal imaging process or a hybrid patterning system (HPS). Thus, according to aspects of embodiments of the present invention, it is possible to improve the characteristic of the organic light emitting diode display.

### BRIEF DESCRIPTION OF THE DRAWINGS

The accompanying drawings, together with the specification, illustrate embodiments of the present invention, and, together with the description, serve to explain the principles of the present invention.

FIG. 1 schematically illustrates an arrangement of organic layers of an organic light emitting diode display according to an exemplary embodiment of the present invention.

FIG. 2 is an equivalent circuit diagram of one pixel of the organic light emitting diode display according to the exemplary embodiment of the present invention.

FIG. 3 is a cross-sectional view of the pixel of the organic light emitting diode display according to the exemplary embodiment of the present invention.

FIG. 4 is a cross-sectional view of a substrate before an organic light emitting layer of the organic light emitting diode display according to the exemplary embodiment of the present invention is deposited on the substrate.

FIG. 5 is a cross-sectional view of a donor film, used when the organic light emitting diode display according to the exemplary embodiment of the present invention is manufactured, on which a transfer layer is deposited.

FIG. 6 illustrates the transfer layer of the donor film being transferred onto a hole transport layer according to the method for manufacturing the organic light emitting diode display according to the exemplary embodiment of the present invention.

### DETAILED DESCRIPTION

The present invention will be described more fully hereinafter with reference to the accompanying drawings, in which certain embodiments of the invention are shown, by way of illustration. As those skilled in the art would realize, the described embodiments may be modified in various different ways, all without departing from the spirit or scope of the present invention.

In the drawings, the thicknesses of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element or it can be indirectly on the other element with one or more intervening elements interposed therebetween. In contrast, when an element is referred to as being “directly on” another element, there are no intervening elements present. Like reference numerals designate like elements throughout the specification. Expressions such as “at least one of,” when preceding a list of elements, modify the entire list of elements and do not modify the individual elements of the list. Further, the use of “may” when describing embodiments of the present invention refers to “one or more embodiments of the present invention.”

Now, an organic light emitting diode display and a method for manufacturing the same according to an exemplary embodiment of the present invention will be described in detail with reference to the accompanying drawings.

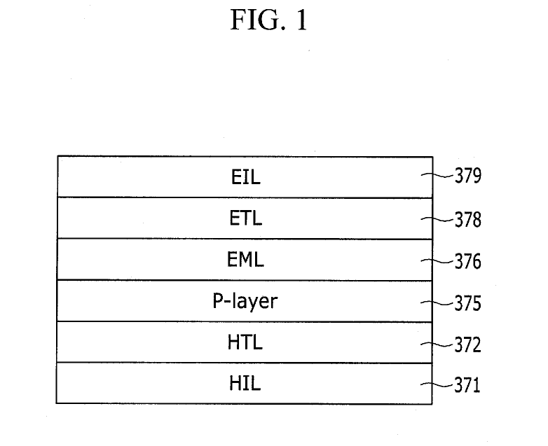

The organic light emitting diode display according to the exemplary embodiment of the present invention will be schematically described with reference to FIG. 1.

First, a laser induced thermal imaging process will be described as a process for forming an organic light emitting layer of the organic light emitting diode display according to the exemplary embodiment of the present invention.

In an embodiment of the laser induced thermal imaging process, a laser beam generated from a laser beam generator is patterned using a mask pattern, a part of a transfer layer is expanded by irradiating the patterned laser beam (e.g., by irradiating a laser beam in a pattern) onto a donor film including a base film and the transfer layer, and the expanded transfer layer is transferred onto the organic light emitting diode display, thereby forming a light emitting layer of the organic light emitting diode display. The laser induced thermal imaging process is capable of minutely patterning the light emission layer (e.g., small patterns of the light emission layer can be formed) and may be performed through a dry process.

At this time, the transfer layer generally includes a single layer of an organic light emitting layer or a double layer of an organic light emitting layer and a resonance supporting layer. When the transfer layer includes a single layer of an organic light emitting layer, thermal energy may be transmitted to a hole transport layer (HTL) of the organic light emitting diode display during the laser induced thermal imaging process, and carrier accumulation may occur at an interface of the hole transport layer and the organic light emitting layer, thereby degrading the characteristic of the organic light emitting diode.

When the transfer layer includes a double layer of an organic light emitting layer and a resonance supporting layer, performance at an interface of the resonance supporting layer and the organic light emitting layer may be improved, but carrier accumulation may occur at an interface of the hole transport layer and the resonance supporting layer, thereby degrading the characteristic of the organic light emitting diode.

Furthermore, when the laser induced thermal imaging process is used, the hole transport layer and the resonance supporting layer may be thermally damaged by the thermal energy generated so as to excessively (or undesirably) increase a driving voltage of the organic light emitting diode, and the thermal energy may be transmitted to the anode, thereby degrading the interfacial characteristic between the anode and a hole injection layer (HIL).

FIG. 1 schematically illustrates an arrangement of organic layers of the organic light emitting diode display according to the exemplary embodiment of the present invention.

As illustrated in FIG. 1, the organic layers of the organic light emitting diode display according to the exemplary embodiment of the present invention include a hole auxiliary layer 371 and 372, a passivation layer (P-layer) 375, an organic light emitting layer (EML) 376, and an electron auxiliary layer 378 and 379, which are sequentially stacked. For example, the organic light emitting diode display may include a hole injection layer (HIL) 371 on (e.g., directly on or disposed over) a pixel electrode, a hole transport layer (HTL) 372 on (e.g., directly on or formed over) the hole injection layer 371, a passivation layer 375 on (e.g., directly on or formed over) the hole transport layer 372, an organic light emitting layer 376 on (e.g., directly on or formed over) the passivation layer 375, an electron transport layer (ETL) 378 on (e.g., directly on or formed over) the organic light emitting layer 376, and an electron injection layer (EIL) 379 on (e.g., directly on or formed over) the electron transport layer 378.

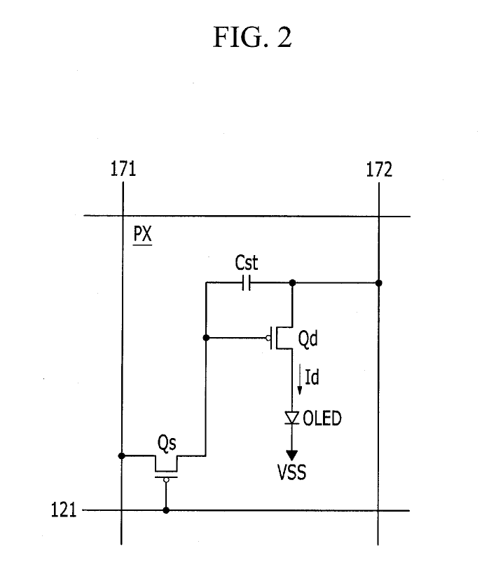

Now, referring to FIG. 2, one pixel of the organic light emitting display device according to the exemplary embodiment of the present invention will be described in detail.

FIG. 2 is an equivalent circuit diagram of one pixel in the organic light emitting diode display according to the exemplary embodiment of the present invention.

Referring to FIG. 2, the organic light emitting diode display according to the exemplary embodiment of the present invention includes a plurality of signal lines 121, 171 and 172, and a pixel PX connected to the plurality of signal lines 121, 171 and 172. The pixel PX may be any one of a red pixel, a green pixel, and a blue pixel.

The signal lines include scanning signal lines 121 to transmit a gate signal (or scanning signal), data lines 171 to transmit a data signal, and driving voltage lines 172 to transmit a driving voltage. The scanning signal lines 121 are extended substantially in a row direction and almost parallel (or substantially parallel) to each other. The data lines 171 are extended substantially in a column direction and almost parallel (or substantially parallel) to each other. FIG. 2 illustrates that the driving voltage line 172 is extended substantially in the column direction. However, the driving voltage line 172 may be extended in the row or column direction or formed in a net shape (e.g., may cross or intersect with one another to form, for example, a grid).

The pixel PX includes a switching transistor Qs (e.g., a thin film transistor), a driving transistor Qd (e.g., a thin film transistor), a storage capacitor Cst, and an organic light emitting element OLED.

The switching transistor Qs has a control terminal, an input terminal, and an output terminal. The control terminal is connected to the scanning signal line 121, the input terminal is connected to the data line 171, and the output terminal is connected to the driving transistor Qd. The switching transistor Qs transmits the data signal received from the data line 171 to the driving transistor Qd in response to the scanning signal received from the scanning signal line 121.

The driving transistor Qd also has a control terminal, an input terminal, and an output terminal. The control terminal is connected to the switching transistor Qs, the input terminal is connected to the driving voltage line 172, and the output terminal is connected to the organic light emitting element OLED. The driving transistor Qd passes an output current Id, of which the magnitude depends upon a voltage applied between the control terminal and the output terminal, to the organic light emitting element.

The capacitor Cst is connected between the control terminal and the input terminal of the driving transistor Qd. The capacitor Cst stores a data signal applied to the control terminal of the driving transistor Qd, and maintains the stored data signal even after the switching transistor Qs is turned off.

The organic light emitting element OLED is an organic light emitting diode (OLED), for example, and has an anode connected to the output terminal of the driving transistor Qd and a cathode connected to a common voltage Vss. The organic light emitting element OLED displays an image by emitting light at different intensities depending on the output current Id of the driving transistor Qd. The organic light emitting element OLED may include an organic material which emits one or more colors of light, for example, any one of the primary colors of red, green and blue, and the organic light emitting diode display displays a desired image through the spatial sum of the colors.

The switching transistor Qs and the driving transistor Qd are n-channel field effect transistors (FET). However, at least one of the switching transistor Qs and the driving transistor Qd may be a p-channel FET. Furthermore, the relationships of the connections among the transistors Qs and Qd, the capacitor Cst, and the organic light emitting element OLED may be changed or modified.

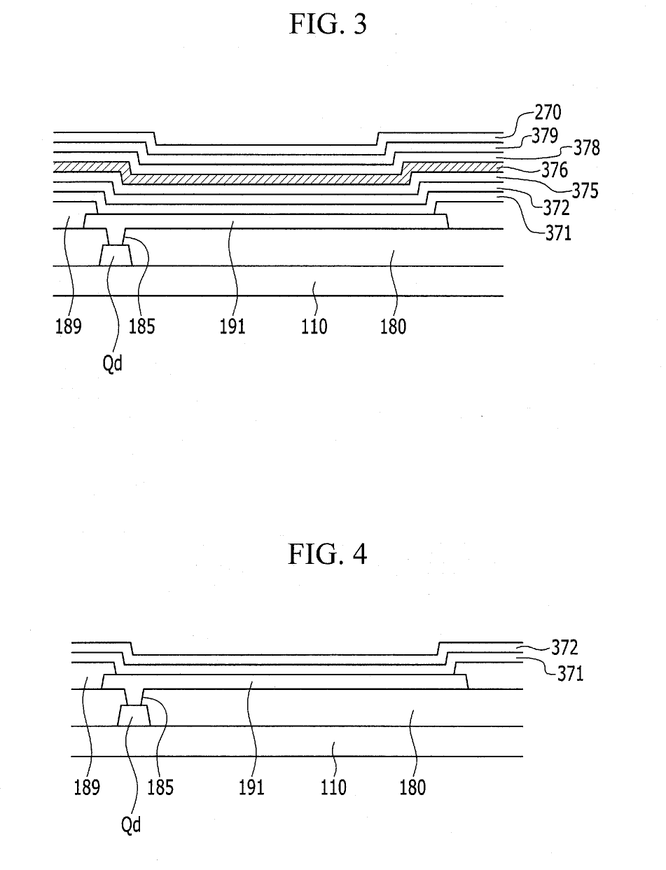

Now, the cross-sectional structure of the organic light emitting diode display according to the exemplary embodiment of the present invention will be described in detail with reference to FIGS. 2 and 3.

FIG. 3 is a cross-sectional view of the pixel of the organic light emitting diode display according to the exemplary embodiment of the present invention.

The driving transistor Qd is on (e.g., directly on or formed over) an insulation substrate 110 made of transparent glass or plastic. In addition, a plurality of signal lines, a plurality of switching transistors and the like may be on (e.g., directly on or formed over) the insulation substrate 110.

An electrode passivation layer 180 including (e.g., made of) an inorganic or organic material is on (e.g., directly on or formed over) the driving transistor Qd. When the electrode passivation layer 180 is made of an organic material, the electrode passivation layer 180 may have a flat surface.

The electrode passivation layer 180 has a contact hole 185 to expose a part of the driving transistor Qd.

A pixel electrode 191 is on (e.g., directly on or formed over) the electrode passivation layer 180 of the pixel. The pixel electrode 191 may include (e.g., be made of) a transparent conductive oxide such as ITO (indium tin oxide) or IZO (indium zinc oxide).

A reflecting layer may be between (e.g., directly contacting both or formed between) the electrode passivation layer 180 and the pixel electrode 191. The reflecting layer may include (e.g., be made of) a metal having high reflectivity, such as silver (Ag) or aluminum (Al), or an alloy thereof.

A pixel defining layer 189 is on (e.g., directly on or formed over) the electrode passivation layer 180 so as to cover an edge of the pixel electrode 191.

A hole auxiliary layer 371 and 372 is on (e.g., directly on or formed on) an entire surface of the pixel electrode 191 in the pixel, and includes a hole injection layer (HIL) 371 and a hole transport layer (HTL) 372 on (e.g., directly on or stacked over) the hole injection layer 371.

A passivation layer 375 is between (e.g., directly contacting both or formed between) the organic light emitting layer 376 and the hole transport layer 372, and an electron auxiliary layer 378 and 379 is on (e.g., directly on or formed on) an entire surface of the organic light emitting layer 376. The electron auxiliary layer 378 and 379 includes an electron transport layer (ETL) 378 and an electron injection layer (EIL) 379 on (e.g., directly on or stacked over) the electron transport layer 378.

The hole injection layer 371, the hole transport layer 372, the electron transport layer 378, and the electron injection layer 379 improve the light emission efficiency of the organic light emitting layer 376. The hole transport layer 372 and the electron transport layer 378 adjust the balance between electrons and holes. The hole injection layer 371 and the electron injection layer 379 strengthen the injection of electrons and holes.

The passivation layer 375 prevents (or reduces) the generation of a mixed layer caused by mixture of the organic light emitting layer 376 and the hole transport layer 372. For example, the passivation layer 375 prevents (or reduces the amount of) formation of the mixed layer as a result of mixing of a material of the organic light emitting 376 and a material of the hole transport layer 372. The organic light emitting layer 376 and the hole transport layer 372 may be mixed as a result of heat generated from the light-to-heat conversion layer during a laser induced thermal imaging process when the organic light emitting diode display is being manufactured. Thus, in order to block thermal energy generated from the light-to-heat conversion layer of the donor film 10 from being transmitted to the hole transport layer 372 (or to reduce the amount of thermal energy transmitted to the hole transport layer 372), the passivation layer 375 may be between (e.g., directly contacting both or formed between) the organic light emitting layer 376 and the hole transport layer 372, and may include (e.g., be made of) a material having a higher melting temperature than the organic light emitting layer 376 and the hole transport layer 372, and of which a phase does not change at a temperature of 400 to 600° C. (e.g., a material that maintains a same phase or substantially same phase at a temperature of 400 to 600° C. under standard pressure or high vacuum conditions).

The passivation layer 375 may include (e.g., be made of) magnesium (Mg), silver (Ag), aluminum (Al), chromium (Cr) and/or gold (Au).

The hole injection layer 371, the hole transport layer 372, the organic light emitting layer 376, the electron transport layer 378, the electron injection layer 379, and the passivation layer 375 form an organic light emitting member.

A common electrode 270 for transmitting a common voltage Vss is on (e.g., directly on or formed over) the electron injection layer 379. The common electrode 270 includes a double layer including a top layer and a bottom layer, and has a transflective characteristic of reflecting a part of light and passing (e.g., transmitting) the other part of the light. Both of the bottom layer and the top layer include (e.g., are made of) a metal which reflects light. However, when the bottom layer and the top layer are formed to have a small thickness (individually or together), the common electrode 270 may have a transflective characteristic of reflecting a portion of incident light and transmitting another portion of the incident light. Furthermore, in other embodiments, the common electrode 270 may include a single layer.

An encapsulation layer may be on (e.g., directly on or formed over) the common electrode 270. The encapsulation layer may encapsulate the organic light emitting member and the common electrode 270 so as to prevent water and/or oxygen from permeating the organic light emitting member from outside.

In the organic light emitting diode display, the pixel electrode 191, the organic light emitting member and the common electrode 270 constitute the organic light emitting element OLED. The pixel electrode 191 may receive a voltage from the driving transistor Qd through the contact hole 185 of the electrode passivation layer 180.

In a top emission display in which light is emitted through the common electrode 270, a reflecting layer is on the pixel electrode 191, the common electrode 270 has a transflective characteristic, and the organic light emitting diode display emits light toward the common electrode 270 so as to display an image. A part of the light emitted from the organic light emitting layer 376 toward the common electrode 270 is transmitted through the common electrode 270, and the other part of the light is reflected toward the pixel electrode 191. The pixel electrode 191 reflects the other part of the light toward the common electrode 270 again. As such, some parts of the light reciprocating between the pixel electrode 191 and the common electrode 270 cause interference. Among the parts of the light, light having a wavelength equal to (or substantially equal to) a distance between the pixel electrode 191 and the common electrode 270 corresponds to light having a wavelength causing resonance, which may cause constructive interference, and the intensity thereof increases. Wavelengths of the other parts of the light may cause destructive interference, and the intensity thereof decreases. The reciprocation and interference processes of light described above relate to a micro cavity.

In other embodiments, the reflecting layer of the pixel electrode 191 may be replaced with a transflective layer and the common electrode 270 may be formed to have a large thickness to reflect light. In this case, it is possible to obtain a bottom emission-type organic light emitting diode display which emits light through the insulation substrate 110.

Hereinafter, a method for manufacturing an organic light emitting diode display according to an exemplary embodiment of the present invention will be described in detail with reference to FIGS. 4 to 6.

In the following description, a transfer layer 20 includes the passivation layer 375 and the organic light emitting layer 376, and the donor film 10 includes a base film 50 and the transfer layer 20.

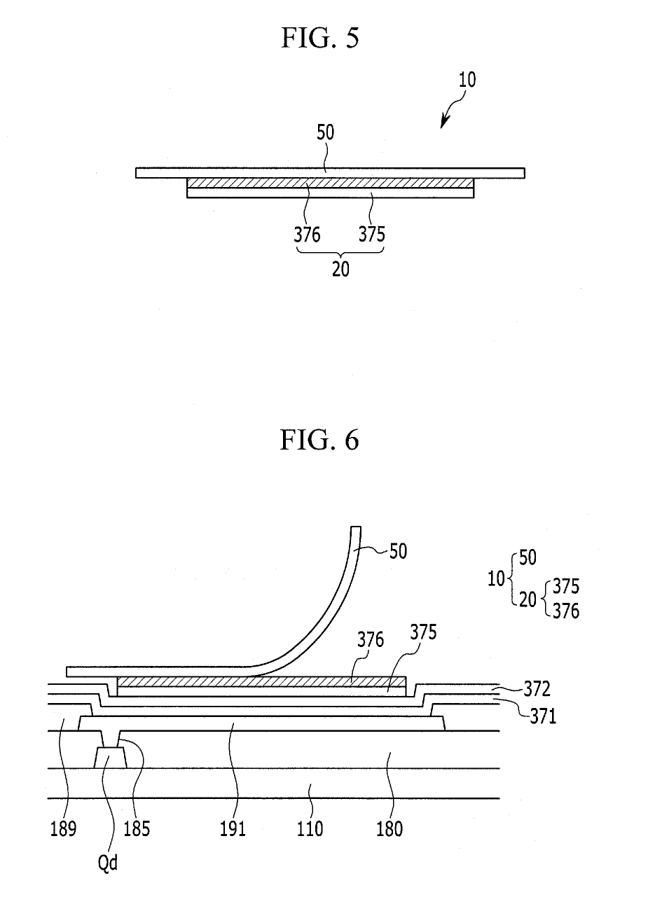

FIG. 4 is a cross-sectional view of the substrate 110 before the organic light emitting layer 376 of the organic light emitting diode display according to the exemplary embodiment of the present invention is deposited. FIG. 5 is a cross-sectional view of the donor film 10 on which the transfer layer 20, which is used when the organic light emitting diode display is manufactured, is deposited. FIG. 6 illustrates a step in which the donor film 10 is transferred onto the hole transport layer 372 according to a method for manufacturing the organic light emitting diode display.

Referring to FIG. 4, the driving transistor Qd is formed over (or on) the insulation substrate 110, and the electrode passivation layer 180 having a contact hole 185 is formed over (or on) the driving transistor Qd.

Then, a conductive oxide member is stacked over (or on) the electrode passivation layer 180 of the pixel and then patterned to form the pixel electrode 191. A reflecting layer may be stacked between the electrode passivation layer 180 and the pixel electrode 191 of the pixel.

Then, the hole injection layer 371 and the hole transport layer 372 are sequentially stacked.

Referring to FIG. 5, the transfer layer 20 is stacked on a base film 50 to be the donor film 10 for transferring the organic light emitting layer 376 onto the substrate having the hole transport layer 372 stacked thereon. Thus, the donor film 10 has a structure in which the base film 50 and the transfer layer 20 are sequentially stacked.

The base film 50 may include (e.g., be made of) a transparent material which has a suitable optical characteristic for transmitting light to a light-to-heat conversion layer and sufficient mechanical stability. For example, the base film 50 may include (e.g., be made of) glass and/or one or more polymer materials selected from the group consisting of polyester, polyacryl, polyepoxy, polyethylene, polystyrene, and polyethylene terephthalate.

The light-to-heat conversion layer may be between (e.g., directly contacting both or formed between) the base film 50 and the transfer layer 20. The light-to-heat conversion layer absorbs light in the range of infrared light to visible light and converts a part or more of the absorbed light into heat. The light-to-heat conversion layer may have a suitable optical density, and may include a light-absorbing material for absorbing light. The light-to-heat conversion layer may include a metal layer including (e.g., made of) Al, Ag, or an oxide or sulfide thereof, and/or an organic layer including (e.g., made of) a polymer containing carbon black, graphite, and/or infrared dye.

The transfer layer 20 is separated from the donor film 10 by the thermal energy received from the light-to-heat conversion layer (e.g., thermal energy generated by the light-to-heat conversion layer causes the transfer layer 20 to expand and separate from the base film 50), and the transfer layer 20 is transferred onto the substrate 110 having the hole transport layer 372 formed therein. The transfer layer 20 has a structure in which the organic light emitting layer 376 and the passivation layer 375 are sequentially stacked.

The passivation layer 375 prevents (or reduces) the generation of a mixed layer by mixture of the organic light emitting layer 376 and the hole transport layer 372, caused by the heat generated from the light-to-heat conversion layer during the laser induced thermal imaging process when the organic light emitting diode display is fabricated. Thus, in order to block the thermal energy generated from the light-to-heat conversion layer of the donor film 10 from being transmitted to the hole transport layer 372 (or to reduce the amount of thermal energy transmitted to the hole transport layer 372), the passivation layer 375 may be between (e.g., directly contacting both or formed between) the organic light emitting layer 376 and the hole transport layer 372, and include (e.g., be made of) a material having a higher melting temperature than the organic light emitting layer 376 and the hole transport layer 372, and of which a phase does not change at a temperature of 400 to 600° C. (e.g., a material that maintains a same phase or substantially same phase at a temperature of 400 to 600° C. under standard pressure or high vacuum conditions).

The passivation layer 375 may include (e.g., be made of) one material of Mg, Ag, Al, Cr and/or Au.

Finally, FIG. 6 illustrates a process of transferring the donor film onto the hole transport layer in the method for manufacturing an organic light emitting diode display according to the exemplary embodiment of the present invention.

As illustrated in FIG. 6, the donor film 10, which includes the organic light emitting layer 376 and the passivation layer 375, is disposed over the hole transport layer 372 of the substrate 110 having the pixel electrode 191 formed thereon.

Then, the hole transport layer 372 is uniformly (or substantially uniformly) laminated on the passivation layer 375 of the donor film 10. Then, laser light is irradiated onto the donor film 10 attached to the hole transport layer 372 so as to transfer the transfer layer 20 of the donor film 10 onto the substrate 110. Thus, the passivation layer 375 and the organic light emitting layer 376 are sequentially formed over (or on) the hole transport layer 372 of the substrate 110.

During the laser induced thermal imaging process, the passivation layer 375 is on (e.g., formed on) the organic light emitting layer 376 of the donor film 10 and transferred onto the hole transport layer 372. Thus, the thermal damage of the organic light emitting layer 376 and the hole transport layer 372 caused by thermal energy may be minimized (or reduced), and the generation of a mixed layer caused by mixture of the organic light emitting layer 376 and the hole transport layer 372 may be suppressed (or reduced) to improve the characteristic of an organic light emitting diode.

Then, the electron transport layer 378, the electron injection layer 379 and the common electrode 270 are sequentially stacked over (or on) the organic light emitting layer 376, and an encapsulation layer is on (e.g., formed on) the resultant structure, thereby completing the organic light emitting diode display.

According to the embodiments of the present invention, as the passivation layer is between (e.g., directly contacting both or formed between) the organic light emitting layer and the hole transport layer, it is possible to minimize (or reduce) thermal damage of the organic light emitting layer and the hole transport layer, caused by thermal energy generated during the laser-induced thermal image process or a hybrid patterning system (HPS). Furthermore, it is possible to prevent (or reduce) the generation of a mixed layer by mixture of the organic light emitting layer and the hole transport layer, caused by heat generated from the light-to-heat conversion layer of the donor film, thereby improving the characteristic of the organic light emitting diode display.

While this invention has been described in connection with what is presently considered to be practical embodiments, it is to be understood that the invention is not limited to the disclosed embodiments, but, on the contrary, is intended to cover various modifications and equivalent arrangements included within the spirit and scope of the appended claims, and equivalents thereof.

Description of some of the symbols

| | |
|---|---|
| 121: Scanning signal line | 10: Donor film |
| 171: Data line | 20: Transfer layer |
| 172: Driving voltage line | 50: Base film |
| PX: Pixel | 110: Substrate |
| Cst: Storage capacitor | 180: Electrode passivation layer |
| Qd: Driving transistor | 191: Pixel electrode |
| Id: Output current | 185: Contact hole |
| OLED: Organic light emitting element | 189: Pixel defining layer |
| Vss: Common voltage | 371: Hole injection layer |
| 372: Hole transport layer | 375: Passivation layer |
| 376: Organic light emitting layer | 378: Electron transport layer |
| 379: Electron injection layer | 270: Common electrode |

What is claimed is:

1. An organic light emitting diode display comprising:
a pixel electrode;
a hole auxiliary layer on the pixel electrode;
a passivation layer on the hole auxiliary layer;
an organic light emitting layer on the passivation layer;
an electron auxiliary layer on the organic light emitting layer; and
a common electrode on the electron auxiliary layer.

2. The organic light emitting diode display of claim 1, wherein:
the passivation layer is for reducing formation of a mixed layer of the organic light emitting layer and the hole auxiliary layer caused by heat.

3. The organic light emitting diode display of claim 2, wherein:
the hole auxiliary layer comprises a hole injection layer on the pixel electrode, and
a hole transport layer on the hole injection layer, and
the electron auxiliary layer comprises an electron transport layer on the organic light emitting layer, and
an electron injection layer on the electron transport layer.

4. The organic light emitting diode display of claim 3, wherein:
the passivation layer comprises a material having a higher melting temperature than the organic light emitting layer and the hole transport layer.

5. The organic light emitting diode display of claim 4, wherein:
the passivation layer comprises a material that resists a phase change at a temperature of 400 to 600° C.

6. The organic light emitting diode display of claim 4, wherein:
the passivation layer is for preventing mixture of the organic light emitting layer and the hole transport layer.

7. The organic light emitting diode display of claim 4, wherein:
the passivation layer comprises a material selected from the group consisting of magnesium (Mg), silver (Ag), aluminum (Al), chromium (Cr) and gold (Au).

8. The organic light emitting diode display of claim 1, wherein:
the passivation layer is for insulating the hole auxiliary layer from heat generated during the manufacture of the organic light emitting diode display.

9. The organic light emitting diode display of claim 1, wherein:
the organic light emitting diode display does not include a mixed layer comprising a mixture of a material of the organic light emitting layer and a material of the hole auxiliary layer.

10. The organic light emitting diode display of claim 1, wherein:
the passivation layer is for preventing a mixed layer of the organic light emitting layer and the hole auxiliary layer from being generated by heat.

11. A method for manufacturing an organic light emitting diode display, the method comprising:
providing a thin film transistor, a pixel electrode and a hole auxiliary layer on a substrate;
providing a light-to-heat conversion layer on a base film, an organic light emitting layer on the light-to-heat conversion layer, and a passivation layer on the organic light emitting layer, thereby manufacturing a donor film;
transferring the organic light emitting layer and the passivation layer of the donor film onto the hole auxiliary layer of the substrate using a laser;
providing the passivation layer on the hole auxiliary layer and the organic light emitting layer on the passivation layer by removing the donor film after transferring the organic light emitting layer and the passivation layer onto the hole auxiliary layer of the substrate; and
providing an electron auxiliary layer on the organic light emitting layer.

12. The method of claim 11, wherein:
the hole auxiliary layer comprises:
a hole injection layer on the pixel electrode, and
a hole transport layer on the hole injection layer; and
the electron auxiliary layer comprises:
an electron transport layer on the organic light emitting layer, and
an electron injection layer on the electron transport layer.

13. The method of claim 12, wherein:
the passivation layer and the organic light emitting layer are transferred onto the hole transport layer on the substrate.

14. The method of claim 12, wherein:
the passivation layer comprises a material having a higher melting temperature than the organic light emitting layer and the hole transport layer.

15. The method of claim 14, wherein:
the passivation layer comprises a material that resists a phase change at a temperature of 400 to 600° C.

16. The method of claim 14, wherein:
the passivation layer prevents mixing of the organic light emitting layer and the hole transport layer caused by heat generated from the light-to-heat conversion layer of the donor film.

17. The method of claim 14, wherein:
the passivation layer comprises one material selected from the group consisting of magnesium (Mg), silver (Ag), aluminum (Al), chromium (Cr) and gold (Au).

18. The method of claim 11, wherein:
the passivation layer reduces mixing of the organic light emitting layer and the hole transport layer caused by heat generated from the light-to-heat conversion layer of the donor film.

19. The method of claim 11, wherein:
the passivation layer insulates the hole auxiliary layer from heat generated by the light-to-heat conversion layer.

20. The method of claim 11, wherein:
the organic light emitting diode display does not include a mixed layer comprising a mixture of a material of the organic light emitting layer and a material of the hole auxiliary layer.
